(19) United States
(12) Patent Application Publication
(10) Pub. No.: US 2013/0115558 A1
(43) Pub. Date: May 9, 2013

(54) SELECTIVE PHOTO-INDUCED PROTEIN IMMOBILIZATION USING BOVINE SERUM ALBUMIN

(71) Applicant: Electronics and Telecommunications Research In, Daejeon (KR)

(72) Inventor: Wan Joong KIM, Goyang (KR)

(73) Assignee: Electronics and Telecommunications Research Institute, Daejeon (KR)

(21) Appl. No.: 13/656,242

(22) Filed: Oct. 19, 2012

(30) Foreign Application Priority Data
Nov. 8, 2011 (KR) 10-2011-0115778

(51) Int. Cl. B05D 3/06; G03F 7/20

(52) U.S. Cl. 430/322; 427/558

(57) ABSTRACT

Provided is a biomaterial immobilizing method including immobilizing a bovine serum albumin on a substrate, providing a biomaterial on the substrate immobilized with the bovine serum albumin, and irradiating an ultraviolet light onto the substrate provided with the bovine serum albumin and the biomaterial to immobilize the biomaterial selectively on the substrate immobilized with the bovine serum albumin.

### CROSS-REFERENCE TO RELATED APPLICATIONS

This U.S. non-provisional patent application claims priority under 35 U.S.C. §119 to Korean Patent Application No. 10-2011-0115778, filed on Nov. 8, 2011, in the Korean Intellectual Property Office, the entire contents of which are hereby incorporated by reference.

### BACKGROUND OF THE INVENTION

Embodiments of the inventive concepts relate to a biomaterial immobilizing method, and in particular, to a selective photo-induced protein immobilization using bovine serum albumin.

Bio- and nano-technologies are regarded as key technologies of the 21st century, along with an information technology. It is being expected that these technologies will be advanced to intensify technological and industrial fusion, not to find their own ways. For this, it is necessary to develop a method of forming a biomaterial or a functional material with a size of nanometer order or molecular level, on the conventional electronic device, to modify a surface of the device. Furthermore, it is necessary to develop a technique capable of maintaining a surface modified with the biomaterial or the functional material stably for a long time and selectively modifying a desired surface.

A micro array of a biomolecule with an active material (e.g., DNA or protein) has been regarded as a basis for studying biological fields, such as diagnostics or proteomics. Especially, compared with a DNA micro array, a protein micro array is widely applicable to many other fields, such as biotechnology, proteome analysis, disease diagnostics, and quantitative analysis.

Generally, a protein immobilization may be achieved through chemical covalent bonding or physical adsorption (e.g., non-covalent bonding) of, for example, glutaric dialdehyde or activated esters or by using photoactivatable crosslinkers, such as NHS-diarzirine. For example, in the case of photo-induced cross-linkers using NHS-ester diazirine with a heterobifunctional group, proteins are immobilized on a surface of a solid body by covalent bonding.

For the photo-induced crosslinking method, there is a technical advantage in obtaining mostly specific binding of activated intermediates in a short time. However, in this method, it is hard to reduce non-specific binding on a chip surface and immobilize specifically a protein in a small space.

Furthermore, since the photoactivatable crosslinkers or NHS-diarzirine should be used, a protein immobilization process in this method is complex. Accordingly, there is a need to develop a protein immobilizing method, in which a non-specific binding can be prevented without the use of photoactivatable crosslinkers.

### SUMMARY

Embodiments of the inventive concepts provide a biomaterial immobilizing method that can immobilize a biomaterial selectively on a localized region of a substrate while reducing a non-specific binding.

According to example embodiments of the inventive concepts, a method of immobilizing a biomaterial may include immobilizing a bovine serum albumin on a substrate, providing a biomaterial on the substrate immobilized with the bovine serum albumin, and irradiating an ultraviolet light onto the substrate provided with the bovine serum albumin and the biomaterial to immobilize the biomaterial selectively on the substrate immobilized with the bovine serum albumin.

In example embodiments, the bovine serum albumin may be immobilized on the substrate by a physical adsorption.

In example embodiments, the bovine serum albumin may cover substantially the entire surface of the substrate.

In example embodiments, the immobilizing of the bovine serum albumin on the substrate may include incubating the bovine serum albumin on the substrate.

In example embodiments, the immobilizing of the biomaterial may include providing a protein on the substrate immobilized with the bovine serum albumin, and irradiating the ultraviolet light onto the substrate to bind the bovine serum albumin selectively with the protein.

In example embodiments, the irradiating of the ultraviolet light may be performed using the ultraviolet light having a wavelength ranging from 200 nm to 400 nm.

In example embodiments, in the immobilizing of the biomaterial, the ultraviolet light may be irradiated onto the substrate for 5-15 min.

In example embodiments, the method may further include providing a photomask with an opening on the substrate. The opening of the photo mask may be used to define an irradiation region of the substrate to be irradiated with the ultraviolet light. The opening of the photo mask may be formed to have a width of about 20 μm.

According to example embodiments of the inventive concepts, a method of immobilizing a biomaterial may include adsorbing a bovine serum albumin on a surface of a substrate, and immobilizing a biomaterial on the substrate adsorbed with the bovine serum albumin.

In example embodiments, the immobilizing of the biomaterial may be performed to immobilize the biomaterial on a localized region of the substrate adsorbed with the bovine serum albumin.

In example embodiments, the immobilizing of the biomaterial may include providing a protein on the substrate immobilized with the bovine serum albumin, and irradiating an ultraviolet light onto the substrate to bind the bovine serum albumin selectively with the protein.

In example embodiments, the irradiating of the ultraviolet light onto the substrate may be performed using a photomask provided on the substrate to include an opening, and the opening of the photo mask may be used to define an irradiation region of the substrate to be irradiated with the ultraviolet light.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIGS. 1A through 1H are schematic diagrams illustrating a method of immobilizing a biomaterial according to according to example embodiments of the inventive concept.

FIG. 2 is a graph showing a technical effect of a method of immobilizing a biomaterial according to example embodiments of the inventive concept.

FIGS. 3A and 3B are schematic diagrams illustrating a method of immobilizing a biomaterial according to according to other example embodiments of the inventive concept.

FIG. 4A is a photograph of a photo mask used in a method of immobilizing a biomaterial according to according to other example embodiments of the inventive concept.

FIG. 4B is a photograph showing a biomaterial immobilized on a substrate using the photo mask of FIG. 4A.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments of the inventive concepts will now be described more fully with reference to the accompanying drawings, in which example embodiments are shown. Example embodiments of the inventive concepts may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Unless otherwise defined, all terms (including technical and scientific terms) used herein have the same meaning as commonly understood by one of ordinary skill in the art to which example embodiments of the inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

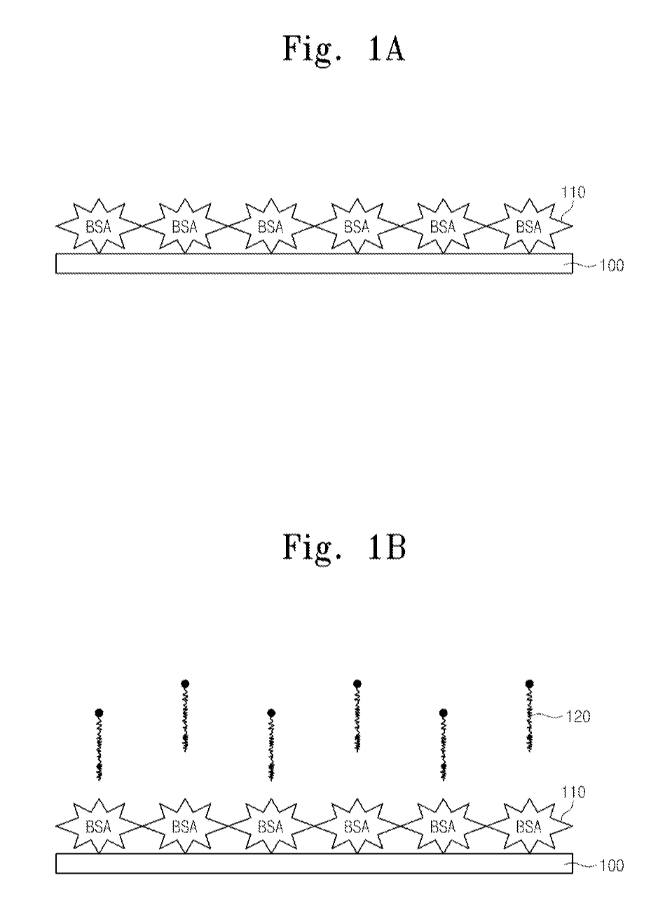

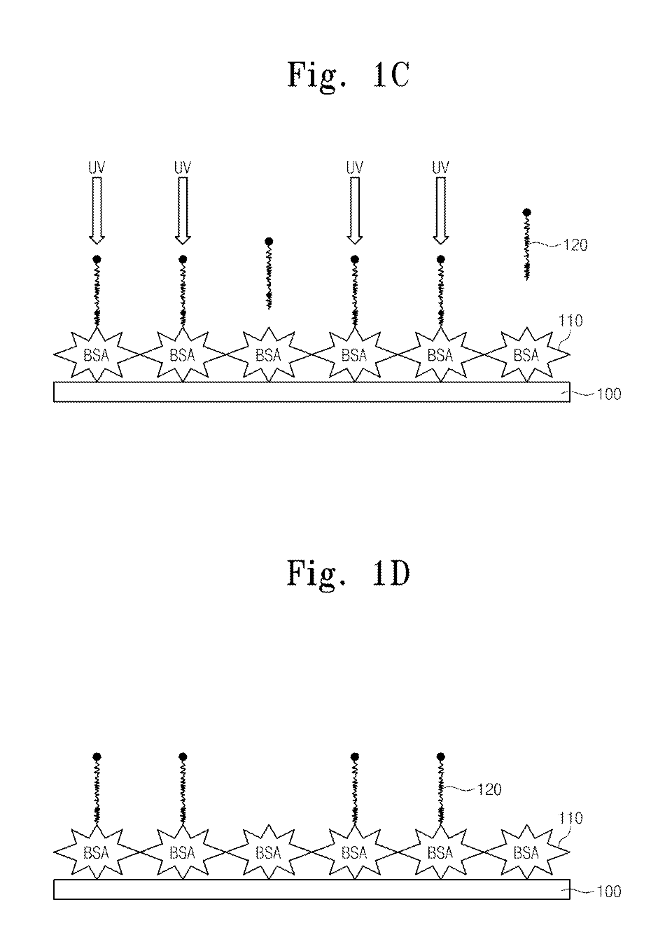

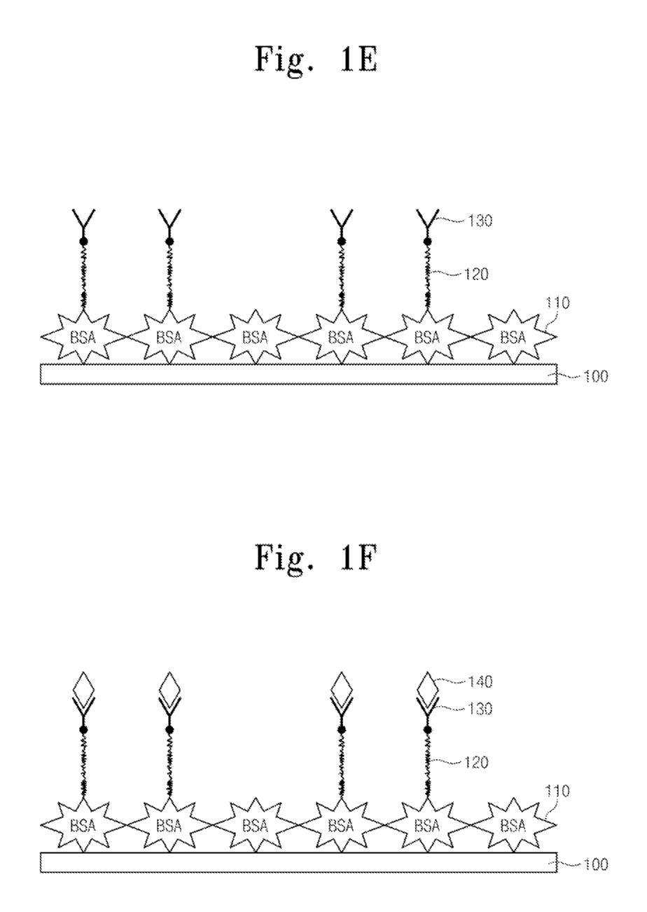

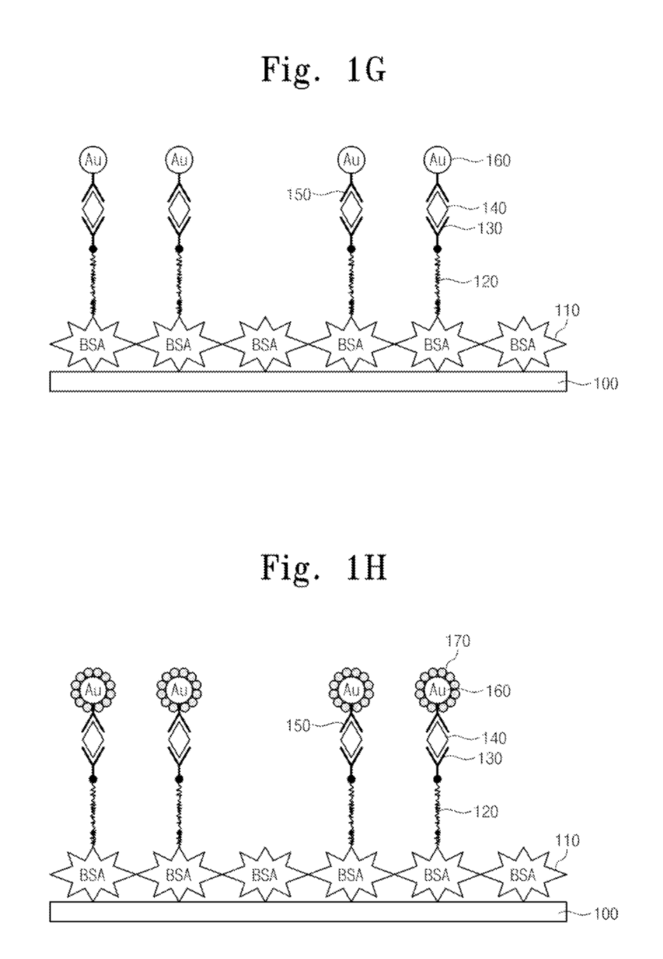

FIGS. 1A through 1H are schematic diagrams illustrating a method of immobilizing a biomaterial according to according to example embodiments of the inventive concepts.

In example embodiments, a protein 120 may be immobilized on a surface of a solid body by using a photoreaction without a crosslinker. For example, the immobilization of the protein 120 may include adsorbing a bovine serum albumin (BSA) 110 onto a surface of a substrate 100, supplying a protein 120 into the substrate 100 adsorbed with the bovine serum albumin 110, and then, irradiating an ultraviolet light (UV) onto the substrate 100 supplied with the protein 120.

Referring to FIG. 1A, the bovine serum albumin 110 may be provided and incubated on the substrate 100. Accordingly, the bovine serum albumin 110 may be physically adsorbed on the substrate 100 to be immobilized. In example embodiments, the bovine serum albumin 110 may be physically adsorbed on the entire surface of the substrate 100. For example, the entire surface of the substrate 100 may be covered with the bovine serum albumin 110, and the bovine serum albumin 110 may prevent the substrate 100 from being nonspecifically bound with an antibody to be supplied thereto.

After the incubation of the bovine serum albumin 110, a washing process may be performed to remove a non-immobilized portion of the bovine serum albumin 110 from the surface of the substrate 100. For example, the washing process may be performed using between 20 (0.01%). In addition, after the washing process, a drying process using nitrogen may be performed.

In example embodiments, the substrate 100 may be a plastic, glass, or silicon substrate. In other example embodiments, the substrate 100 may be a substrate including a transparent oxide, such as titanium oxide (TiO₂), tantalum oxide (Ta₂O₅), or aluminum oxide (Al₂O₃). Alternatively, the substrate 100 may include a transparent polymer, such as polydimethylsiloxane (PDMS), polymethylmethacrylate (PMMA), polycarbonate (PC), cyclic copolymer (COC), polyamide (PA), polyethylene (PE), polypropylene (PP), polyphenylene ether (PPE), polystyrene (PS), polyoxymethylene (POM), polyetheretherketone (PEEK), polytetrafluoroethylene (PTFE), polyvinylchloride (PVC), polyvinylidene fluoride (PVDF), polybutyleneterephthalate (PBT), fluorinated ethylenepropylene (FEP), or perfluoralkoxyalkane (PFA).

Referring to FIG. 1B, the protein 120 may be provided on the substrate 100 adsorbed with the bovine serum albumin 110. Here, the protein 120 may be selected to be bindable with Fc domain of an antibody to be introduced in the subsequent step. For example, the protein 120 may immobilize an antibody with maintaining its orientation, such that the antibody can be specifically bound with an antigen. The protein 120 may be strongly bound with Fc domain of the antibody, which may not participate in the antigen-antibody reaction, and this enable to improve accessibility of the antigen. Furthermore, since the binding between the protein 120 and the antibody may be achieved without any additional chemical modification, it is possible to preserve an inherent property of the antibody.

In example embodiments, the protein 120 may be at least one selected from a group including materials based on immunoglobulin G (IgG). For example, a protein A, a protein G, or a protein A/G may be provided on the substrate 100 adsorbed with the bovine serum albumin 110.

Referring to FIG. 1C, after the providing of the protein 120, an ultraviolet light UV may be selectively irradiated onto the substrate 100. In other words, the ultraviolet light UV may be locally irradiated onto the protein 120 to be immobilized. In example embodiments, the ultraviolet light may have a wavelength ranging from about 200 nm to about 400 nm. For example, an ultraviolet light having a wavelength of about 365 nm and an intensity of 18 W/m may be irradiated onto the substrate 100, for about 10-15 min.

The ultraviolet light irradiated onto the substrate 100 may be absorbed by aromatic groups (e.g., tryptophan) of the bovine serum albumin 110, and an energy thereof may be delivered to neighboring dithiol bond (S—S; disulfide bond). As a result, the dithiol bond may be easily cut to form activated thiol (—S; sulfide). Very unstable thiol (—S) may attack a backbone of amino acid or peptide of the protein 120, thereby specifically binding the bovine serum albumin 110 with the protein 120. Accordingly, as shown in FIG. 1D, the protein 120 may be selectively immobilized on the bovine serum albumin 110 irradiated with the ultraviolet light. In other words, the protein 120 may be locally immobilized on portions of the substrate 100. After the selective immobilization of the protein 120, a washing process may be performed to remove remnants of the protein 120 not immobilized on the substrate 100.

Referring to FIG. 1E, an antibody 130 to be immobilized may be supplied onto the substrate 100 and be incubated, after the immobilization of the protein 120 using the ultraviolet light. Since the protein 120 may be bondable with the Fc domain of the antibody as described above, the antibody 130 may be selectively immobilized on the substrate 100 with maintaining its orientation. For example, the Fc domain of the antibody 130 may be bonded with the protein 120, such that the antibody 130 can be selectively immobilized on the substrate 100.

After the selective immobilization of the antibody 130 on the substrate 100, a silver enhancement method may be used to examine whether the antibody 130 is immobilized or not.

For example, as shown in FIG. 1F, an antigen 140, which can form specific binding with the antibody 130, may be supplied and incubated on the substrate 100 immobilized with the antibody 130. Then, the antigen 140 may be immobilized on the substrate 100 by an antigen-antibody reaction.

Thereafter, as shown in FIG. 1G, a conjugate including a polyclonal antibody 150 bonded to a gold nanoparticle 160 may be provided. The polyclonal antibody 150 may be specifically bonded with the antigen 140 captured on the antibody 130. The polyclonal antibody 150 may be bound with the gold nanoparticle 160 by chemical adsorption, covalent-binding, electrostatic attraction, co-polymerization, or an avidin-biotin affinity system. In example embodiments, the antibody 150 bound with the gold nanoparticle 160 may be polyclonal, but be monoclonal in certain embodiments.

As the result of the binding between the polyclonal the antibody 150 and the antigen 140, a conjugate, in which the bovine serum albumin 110, the protein 120, the antibody 130, the antigen 140, the polyclonal antibody 150, and the gold nanoparticle 160 are bound in sequentially, may be selectively immobilized on the substrate 100.

Thereafter, as shown in FIG. 1H, a silver enhancer containing silver ions 170 may be provided to surround the gold nanoparticle 160. The providing of the silver ions 170 may be performed, until the silver ions 170 around the gold nanoparticle 160 are sufficiently large to be observed by naked eye.

Reactivity with respect to the gold nanoparticle 160 may be measured using an enzyme immuno-assay or immune-precipitation method, such as a radio immunoassay (RIA) or an enzyme-linked immuno-solvent assay (ELISA), instead of the silver enhancement method. In addition, a surface plasmon resonance (SPR) equipment may be used to measure the gold bondability quantitatively.

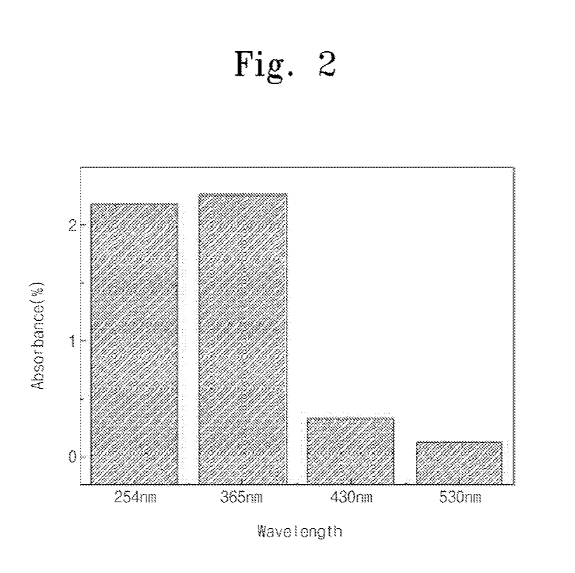

FIG. 2 is a graph showing a technical effect of a method of immobilizing a biomaterial according to example embodiments of the inventive concept. In more detail, samples used in the experiment were prepared using the biomaterial immobilizing method according to example embodiments of the inventive concept. In the experiment, the proteins were immobilized using ultraviolet lights having different wavelengths from each other. In FIG. 2, the horizontal axis represents the wavelengths of the ultraviolet lights used in the experiment, and the vertical axis represents absorbance of the samples measured by the silver enhancement method.

Proteins were immobilized on a substrate by irradiating ultraviolet lights of 254 nm, 365 nm, 430 nm, and 530 nm for 10 min, as described with reference to FIG. 1C. Thereafter, an antibody was supplied and incubated to form a protein A/G photoselectively on an Fc domain of the antibody. The antibody was one of IgG-based materials. After the antibody was immobilized with maintaining its orientation, an antigen, which can form a specific binding with the antibody, was supplied and incubated. Thereafter, the silver enhancement method described with reference to FIG. 1H was used to measure absorbance of a gold nanoparticle. In other words, a gold nanoparticle bound with polyclonal antibody was supplied and a silver enhancer agent was supplied to bond silver ions on the gold nanoparticle. Next, the absorbance of the gold nanoparticle was measured.

According to the experimental example of the inventive concept, ultraviolet lights of 254 nm, 365 nm, 430 nm, and 530 nm were irradiated to selectively immobilize proteins on the substrate, as described with reference to FIGS. 1A through 1D. Thereafter, gold nanoparticles were bound using sandwich immunoreaction as described with reference to FIGS. 1E through 1g, and a silver enhancement method was used to examine the immobilization of the protein as described with reference to FIG. 1H. In more detail, the biomaterial immobilizing method according to example embodiments of the inventive concept was performed as follows.

A) 96 well plate was prepared, and 50 μm bovine serum albumin was used to block a surface of the 96 well plate.

B) 0.5 mg/mL protein A/G (25 μm) was supplied on the 96 well plate, and thereafter, ultraviolet lights of 254 nm, 365 nm, 430 nm, and 530 nm were irradiated onto the 96 well plate for 10 min.

C) 0.05 mg/mL monoclonal PSA antibody (50 μm) was supplied and incubated for 1 hour.

D) 500 ng/mL PSA antigen (50 μm) was supplied and incubated for 1 hour.

E) Gold nanoparticles (50 μm) bound with 4 nM polyclonal PSA antibody was supplied and incubated for 1 hour.

F) Silver enhancers A and B containing Ag⁺ (25 μL) were supplied and incubated for 10 min.

G) The resultant was washed several times with distilled water.

Referring to FIG. 2 showing the result obtained from the samples prepared by the above biomaterial immobilizing method, in the cases of irradiating the ultraviolet lights of 254 nm and 365 nm, the measured absorbance was higher than 2, which means that the protein was selectively immobilized. By contrast, in the cases of irradiating the ultraviolet lights of 430 nm and 530 nm, the measured absorbance was lower than 0.5, which means that the protein was insufficiently immobilized. From this, it can be said that a light having a wavelength ranging from about 200 nm to about 400 nm can be used for a selective immobilization of protein.

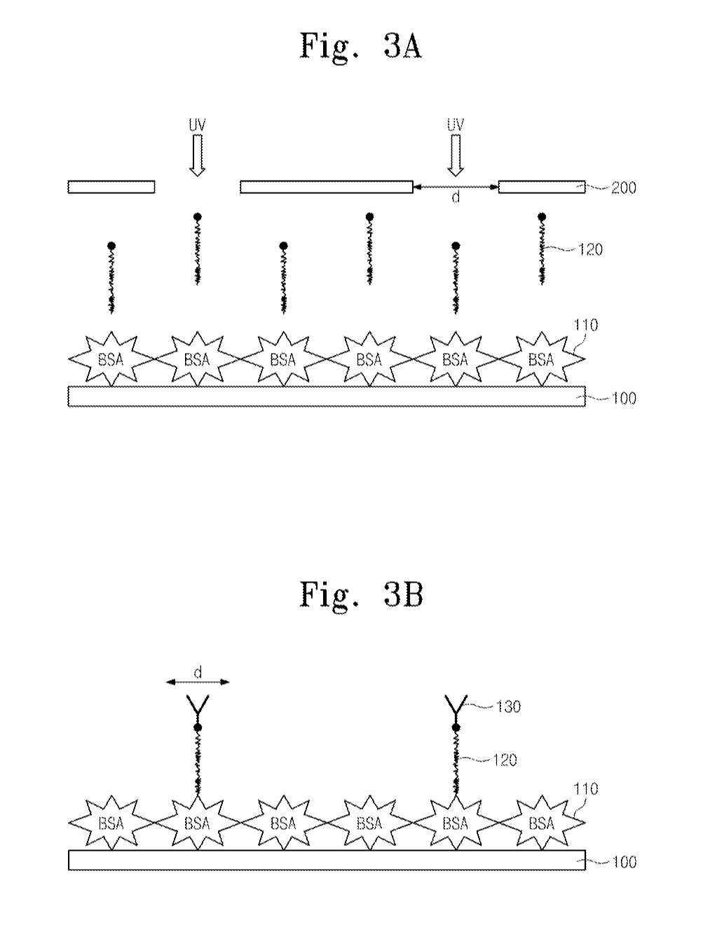

FIGS. 3A and 3B are schematic diagrams illustrating a method of immobilizing a biomaterial according to according to other example embodiments of the inventive concept.

Referring to FIGS. 3A and 3B, a photo mask 200 may be used to immobilize the protein 120 selectively on the substrate 100. For example, as described with reference to FIGS. 1A and 1b, the bovine serum albumin 110 may be adsorbed on a surface of the substrate 100, and then, the protein 120 may be provided on the substrate 100.

Thereafter, the photo mask 200 with openings may be used in a process of selectively irradiating an ultraviolet light onto the substrate 100. In example embodiments, the ultraviolet light may have a wavelength of 365 nm and a power of 18 W/m, and the opening of the photo mask 200 may be formed to have a width d of, for example, 20 μm. As the result of the irradiation process, as shown in FIG. 3B, the protein 120 may be selectively immobilized on the bovine serum albumin 110 to form a fine pattern having a width d of about 20 μm.

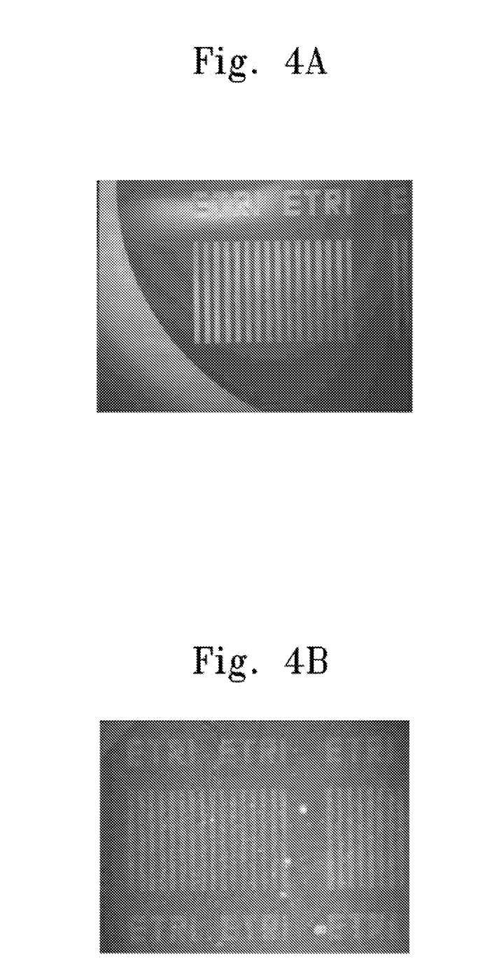

FIGS. 4A and 4B are images provided to explain an immobilization method according to other example embodiments of the inventive concept. In detail, FIG. 4A is a photograph of a photo mask used in a method of immobilizing a biomaterial according to according to other example embodiments of the inventive concept, and FIG. 4B is a photograph showing a biomaterial immobilized on a substrate using the photo mask of FIG. 4A. Each letter shown in FIGS. 4A and 4B had a size of about 20 μm. In other words, it can be said, from FIGS. 4A and 4B, that a selective irradiation of an ultraviolet light can be used to immobilize an antibody having a width of about 20 μm selectively at a desired position.

A biomaterial immobilizing method according to example embodiments of the inventive concept, a protein may be immobilized on a surface of a solid body by using bovine serum albumin, without using a photo-crosslinker (e.g., NHS-Diazirine).

In this method, the bovine serum albumin may serve as firstly a blocker helping a selective protein immobilization and secondly a crosslinker connecting the solid body and the protein.

For example, the bovine serum albumin may be physically adsorbed on a solid body, and an ultraviolet light may be used to selectively bind the protein (e.g., protein A/G) thereon. Thereafter, an antibody may be immobilized while maintaining its aromaticity.

While example embodiments of the inventive concepts have been particularly shown and described, it will be understood by one of ordinary skill in the art that variations in form and detail may be made therein without departing from the spirit and scope of the attached claims.

What is claimed is:

1. A method of immobilizing a biomaterial, comprising:
immobilizing a bovine serum albumin on a substrate;
providing a biomaterial on the substrate immobilized with the bovine serum albumin; and
irradiating an ultraviolet light onto the substrate provided with the bovine serum albumin and the biomaterial to immobilize the biomaterial selectively on the substrate immobilized with the bovine serum albumin.

2. The method of claim 1, wherein the bovine serum albumin is immobilized on the substrate by a physical adsorption.

3. The method of claim 1, wherein the bovine serum albumin covers substantially the entire surface of the substrate.

4. The method of claim 1, wherein the immobilizing of the bovine serum albumin on the substrate comprises incubating the bovine serum albumin on the substrate.

5. The method of claim 1, wherein the immobilizing of the biomaterial comprises:
providing a protein on the substrate immobilized with the bovine serum albumin; and
irradiating the ultraviolet light onto the substrate to bind the bovine serum albumin selectively with the protein.

6. The method of claim 1, wherein the irradiating of the ultraviolet light is performed using the ultraviolet light having a wavelength ranging from 200 nm to 400 nm.

7. The method of claim 1, wherein in the immobilizing of the biomaterial, the ultraviolet light is irradiated onto the substrate for 5-15 min.

8. The method of claim 1, further comprises providing a photomask with an opening on the substrate,
wherein the opening of the photo mask is used to define an irradiation region of the substrate to be irradiated with the ultraviolet light.

9. The method of claim 8, wherein the opening of the photo mask is formed to have a width of about 20 μm.

10. A method of immobilizing a biomaterial, comprising:
adsorbing a bovine serum albumin on a surface of a substrate; and
immobilizing a biomaterial on the substrate adsorbed with the bovine serum albumin.

11. The method of claim 10, wherein the immobilizing of the biomaterial is performed to immobilize the biomaterial on a localized region of the substrate adsorbed with the bovine serum albumin.

12. The method of claim 10, wherein the immobilizing of the biomaterial comprises:
providing a protein on the substrate immobilized with the bovine serum albumin; and
irradiating an ultraviolet light onto the substrate to bind the bovine serum albumin selectively with the protein.

13. The method of claim 12, wherein the irradiating of the ultraviolet light onto the substrate is performed using a photomask provided on the substrate to include an opening, and the opening of the photo mask is used to define an irradiation region of the substrate to be irradiated with the ultraviolet light.
